(19) United States
(12) Patent Application Publication
(10) Pub. No.: US 2026/0333751 A1
(43) Pub. Date: Oct. 22, 2026

(54) SEMICONDUCTOR DEVICE AND PRODUCTION METHOD THEREFOR

(71) Applicant: TOYODA GOSEI CO., LTD., Kiyosu-shi (JP)

(72) Inventor: Go NISHIO, Kiyosu-shi (JP)

(21) Appl. No.: 19/468,388

(22) Filed: Feb. 3, 2026

(30) Foreign Application Priority Data
Feb. 5, 2025 (JP) 2025-017512

(51) Int. Cl. H10D 30/66; H10D 30/01; H10D 62/10; H10D 62/13; H10D 64/23

(52) U.S. Cl. CPC H10D 30/668; H10D 30/0295; H10D 30/0297; H10D 62/127; H10D 62/153; H10D 64/2527

(57) ABSTRACT

A semiconductor device includes: a substrate; a main drift layer; a second conductivity type blocking layer; a second conductivity type connection layer; a source electrode; a sub-drift layer; a second conductivity type body layer; a high concentration first conductivity type impurity-containing layer; a gate trench formed in a groove shape to reach at least the sub-drift layer from the high concentration first conductivity type impurity-containing layer and to expose at least a part of a side surface of the second conductivity type connection layer; a gate insulating film provided in a film shape along a bottom surface and a side surface of the gate trench and covering the side surface of the second conductivity type connection layer exposed in the gate trench; and a gate electrode provided along the bottom surface and the side surface of the gate trench via the gate insulating film.

### CROSS-REFERENCE TO RELATED APPLICATION

This application is based on and claims priority under 35 USC 119 from Japanese Patent Application No. 2025-017512 filed on Feb. 5, 2025.

### TECHNICAL FIELD

The present invention relates to a semiconductor device and a production method therefor.

### BACKGROUND ART

In a semiconductor device having a gate trench structure, in an off state in which a gate voltage is less than a threshold value, a leakage current is likely to be generated due to electrolysis concentration on a bottom portion of a gate trench, and thus a breakdown voltage tends to be low. Therefore, in a configuration disclosed in Patent Literature 1, a p-type blocking layer is provided between a p-type body layer and an n-type drift layer to alleviate electrolysis concentration on a bottom portion of a gate trench and to prevent current leakage, thereby improving a breakdown voltage. Further, when the p-type blocking layer is electrically floated, electric charges are accumulated in the p-type blocking layer to increase a switching loss in a semiconductor, so that the p-type blocking layer and a source electrode are connected to release the electric charges.

Patent Literature 1: JP2019-054174A

### SUMMARY OF INVENTION

In the configuration disclosed in Patent Literature 1, in order to connect the p-type blocking layer and the source electrode, a deep trench that is a groove leading from the source electrode to the p-type blocking layer is formed, and a p-type connection layer containing a p-type impurity is formed in the deep trench. However, when forming the p-type connection layer, a wall surface of the deep trench is exposed to the atmosphere, so that impurities such as Si adhere to the wall surface and a high concentration n-type region containing an n-type impurity at a high concentration is formed. Then, since the high concentration n-type region serves as a leakage path for energizing the source electrode and a drain electrode, when a voltage is applied between the two electrodes, a leakage current is generated, and the breakdown voltage decreases. Note that, although it is conceivable to prevent impurities from adhering to the wall surface of the deep trench or to clean the wall surface of the deep trench to remove the impurities adhering to the wall surface before forming the p-type connection layer, such an operation is not easy and is not realistic. Therefore, in a semiconductor device having a gate trench structure, there is a room for improvement in achieving both an improvement in breakdown voltage and a reduction in switching loss.

The present invention has been made in view of such a background, and an object of the present invention is to provide a semiconductor device capable of achieving both an improvement in breakdown voltage and a reduction in switching loss.

An aspect of the present invention provides a semiconductor device including:
a substrate made of a semiconductor containing a first conductivity type impurity;
a main drift layer provided on the substrate and containing a first conductivity type impurity at a lower concentration than the substrate;
a second conductivity type blocking layer provided on and in contact with the main drift layer, having an opening, and containing a second conductivity type impurity;
a second conductivity type connection layer provided on the second conductivity type blocking layer and containing a second conductivity type impurity at a higher concentration than the second conductivity type blocking layer;
a source electrode connected to the second conductivity type connection layer;
a sub-drift layer filling the opening, provided on the second conductivity type blocking layer, and containing a first conductivity type impurity at a same concentration as the main drift layer or at a higher concentration than the main drift layer;
a second conductivity type body layer provided on the sub-drift layer and the second conductivity type blocking layer, and containing a second conductivity type impurity at a same concentration as the second conductivity type blocking layer or at a lower concentration than the second conductivity type blocking layer;
a high concentration first conductivity type impurity-containing layer provided on the second conductivity type body layer and containing a first conductivity type impurity at a higher concentration than the sub-drift layer;
a gate trench formed in a groove shape to reach at least the sub-drift layer from the high concentration first conductivity type impurity-containing layer and to expose at least a part of a side surface of the second conductivity type connection layer;
a gate insulating film provided in a film shape along a bottom surface and a side surface of the gate trench and covering the side surface of the second conductivity type connection layer exposed in the gate trench; and
a gate electrode provided along the bottom surface and the side surface of the gate trench via the gate insulating film.

Another aspect of the present invention provides a method for producing the above semiconductor device, the method including:
a preparation step of preparing a stacked body in which the substrate, the main drift layer, the second conductivity type blocking layer, the sub-drift layer, the second conductivity type body layer, and the high concentration first conductivity type impurity-containing layer are stacked;
a deep trench forming step of forming a deep trench, which is a groove reaching at least the second conductivity type blocking layer from the high concentration first conductivity type impurity-containing layer in the stacked body;
a second conductivity type connection layer forming step of forming the second conductivity type connection layer so as to fill the deep trench;
a gate trench forming step of forming the gate trench by removing a region including a junction portion between a peripheral surface of the second conductivity type connection layer and a wall surface of the deep trench from the high concentration first conductivity type impurity-containing layer to at least the sub-drift layer to expose at least a part of the side surface of the second conductivity type connection layer;
a gate insulating film forming step of forming the gate insulating film covering the bottom surface and the side surface of the gate trench;
a gate electrode forming step of forming the gate electrode along the bottom surface and the side surface of the gate trench via the gate insulating film; and
a source electrode forming step of forming the source electrode connected to the second conductivity type connection layer.

In the semiconductor device according to the one aspect, the second conductivity type blocking layer is provided between the second conductivity type body layer and the main drift layer to alleviate electrolysis concentration on a bottom portion of the gate trench and prevent current leakage, thereby improving a breakdown voltage. Further, by connecting the second conductivity type blocking layer and the source electrode by the second conductivity type connection layer, the second conductivity type blocking layer is prevented from electrically floating, and occurrence of a switching loss is prevented. In addition, since the gate trench is formed to expose at least a part of the side surface of the second conductivity type connection layer and the side surface of the second conductivity type connection layer exposed in the gate trench is covered by the gate insulating film covering the wall surface of the gate trench, at least a part of a high concentration n-type region on the side surface of the second conductivity type connection layer can be removed and the side surface can be insulated. As a result, formation of a leakage path is prevented, and a decrease in breakdown voltage can be prevented. Therefore, according to the one aspect, it is possible to provide a semiconductor device capable of achieving both an improvement in breakdown voltage and a reduction in switching loss.

In addition, in the method for producing a semiconductor device according to the another aspect, the gate trench is formed by removing the region including the junction portion between the peripheral surface of the second conductivity type connection layer and the wall surface of the deep trench from the high concentration first conductivity type impurity-containing layer to at least the sub-drift layer, at least a part of the side surface of the second conductivity type connection layer is exposed to the wall surface of the gate trench, and the side surface of the second conductivity type connection layer exposed to the wall surface of the gate trench is covered with the gate insulating film. Accordingly, with the production method according to the other aspect, it is possible to produce the semiconductor device according to the one aspect capable of achieving both an improvement in breakdown voltage and a reduction in switching loss.

### BRIEF DESCRIPTION OF DRAWINGS

FIG. 1 is a cross-sectional view showing a configuration of a semiconductor device according to a first embodiment, which is a cross-sectional view perpendicular to a substrate main surface at a position of a line A-A' in (a) of FIG. 2.

FIG. 2 is a drawing in which (a) is a diagram showing an example of a plane pattern of a trench, a second conductivity type connection layer, and a second conductivity type body layer, (b) is a diagram showing another example of the plane pattern of the trench, the second conductivity type connection layer, and the second conductivity type body layer, and (c) is a diagram showing still another example of the plane pattern of the trench, the second conductivity type connection layer, and the second conductivity type body layer in the first embodiment.

FIG. 3 is a flowchart showing a method for producing a semiconductor device according to the first embodiment.

FIG. 4 is a diagram showing a step of producing the semiconductor device according to the first embodiment.

FIG. 5 is a diagram showing a step of producing the semiconductor device according to the first embodiment.

FIG. 6 is a diagram showing a step of producing the semiconductor device according to the first embodiment.

FIG. 7 is a diagram showing a step of producing the semiconductor device according to the first embodiment.

FIG. 8 is a diagram showing a step of producing the semiconductor device according to the first embodiment.

FIG. 9 is a diagram showing a step of producing the semiconductor device according to the first embodiment.

FIG. 10 is a diagram showing a step of producing the semiconductor device according to the first embodiment.

FIG. 11 is a diagram showing a step of producing the semiconductor device according to the first embodiment.

FIG. 12 is a diagram showing a step of producing the semiconductor device according to the first embodiment.

FIG. 13 is a cross-sectional view showing a configuration of a semiconductor device according to a second embodiment, which is a cross-sectional view perpendicular to a substrate main surface.

FIG. 14 is a cross-sectional view showing a configuration of a semiconductor device according to a first modification, which is a cross-sectional view perpendicular to a substrate main surface.

FIG. 15 is a cross-sectional view showing a configuration of a semiconductor device according to a third embodiment, which is a cross-sectional view perpendicular to a substrate main surface.

FIG. 16 is a flowchart showing a method for producing a semiconductor device according to the third embodiment.

FIG. 17 is a diagram showing a step of producing the semiconductor device according to the third embodiment.

FIG. 18 is a diagram showing a step of producing the semiconductor device according to the third embodiment.

FIG. 19 is a diagram showing a step of producing the semiconductor device according to the third embodiment.

### DESCRIPTION OF EMBODIMENTS

In the semiconductor device, it is preferable that the second conductivity type connection layer has a projecting portion projecting toward the opening along the bottom surface of the gate trench, and a projecting amount of the projecting portion projecting from the side surface of the gate trench is smaller than a width of the bottom surface of the gate trench. In this case, a function of a transistor portion formed in a region including the opening in the semiconductor device can be ensured.

In the semiconductor device, it is preferable that a bottom surface of the second conductivity type connection layer is located closer to a side where the high concentration first conductivity type impurity-containing layer is located than the bottom surface of the gate trench is. In this case, since the second conductivity type connection layer does not project to the bottom surface of the gate trench, the breakdown voltage can be further improved.

In the semiconductor device, it is preferable that the entire side surface of the second conductivity type connection layer is exposed to the gate trench and covered with the gate insulating film. In this case, it is possible to further improve the breakdown voltage and reduce the switching loss.

It is preferable that the semiconductor device, further includes: a recess formed in a groove shape to reach the second conductivity type body layer from the high concentration first conductivity type impurity-containing layer; and a second conductivity type hole filling layer provided to fill the recess and containing a second conductivity type impurity at a higher concentration than the second conductivity type blocking layer, in which the source electrode includes a first source electrode and a second source electrode provided to cover the second conductivity type hole filling layer. In this case, the breakdown voltage of the semiconductor device can be further improved.

It is preferable that the method for producing a semiconductor device further includes: a recess forming step of forming the recess by removing a region above the opening from the high concentration first conductivity type impurity-containing layer to the second conductivity type body layer after the deep trench forming step, in which after the recess forming step, in the second conductivity type connection layer forming step, the deep trench is filled to form the second conductivity type connection layer, and the recess is filled to form a second conductivity type hole filling layer. In this case, the breakdown voltage of the semiconductor device can be further improved.

### First Embodiment

### 1. Configuration of Semiconductor Device

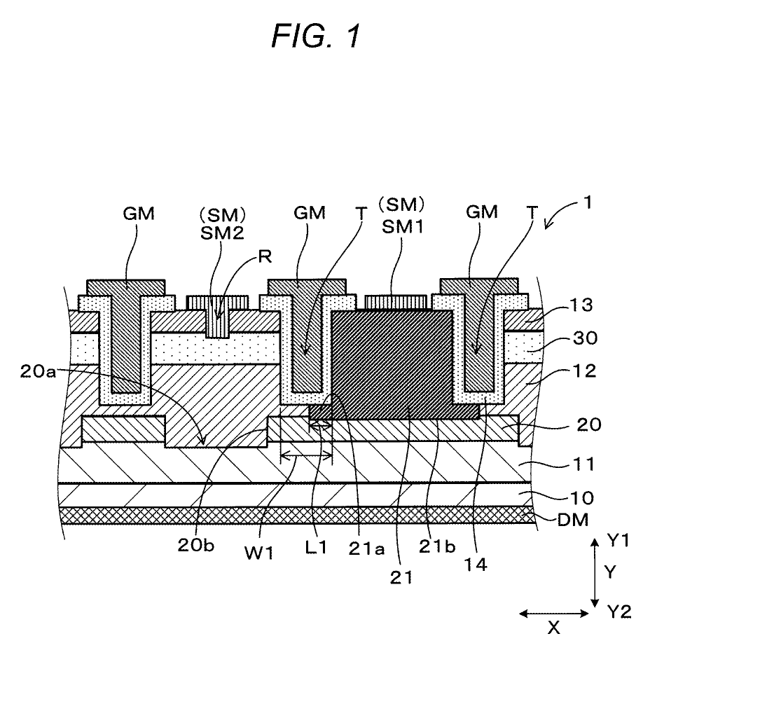

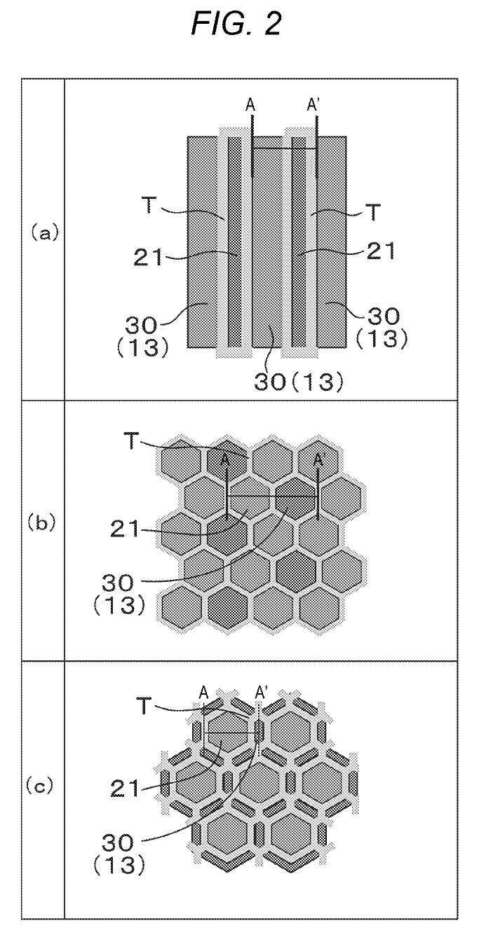

FIG. 1 is a cross-sectional view showing a configuration of a semiconductor device according to a first embodiment, which is a cross-sectional view perpendicular to a substrate main surface. The semiconductor device according to the first embodiment is a MOSFET having a gate trench structure. The semiconductor device according to the first embodiment can have a structure in which a gate trench and a p-type connection layer, to be described later, are arranged in a stripe shape as shown in (a) of FIG. 2, or a structure in which regular hexagonal unit cells are arranged in a honeycomb shape and the unit cells are connected in parallel as shown in (b) and (c) of FIG. 2, in a plan view.

As shown in FIG. 1, the semiconductor device according to the first embodiment includes a substrate 10, a main drift layer 11, a sub-drift layer 12, a second conductivity type blocking layer 20, a second conductivity type connection layer 21, a second conductivity type body layer 30, a high concentration first conductivity type impurity-containing layer 13, a gate trench T, a recess R, a gate insulating film 14, a gate electrode GM, a source electrode SM, and a drain electrode DM. The gate trench T, the gate insulating film 14, and the gate electrode GM constitute a gate trench structure. All of the gate trench structures are MIS structures.

The substrate 10 is made of a semiconductor containing a first conductivity type impurity, and is made of Si-doped n⁺-GaN having a c plane as a main surface in the present embodiment. A Si concentration in the substrate 10 can be 5 × 10¹⁷/cm³ to 5 × 10²⁰/cm³, and is 2 × 10¹⁸/cm³ in the present embodiment. A thickness of the substrate 10 may be 100 μm to 500 μm, and is 300 μm in the present embodiment. A material of the substrate 10 may be a material other than GaN, and any material can be used as long as the material can grow a nitride semiconductor and has conductivity. For example, Si, SiC, or ZnO can be used. However, it is preferable to use a nitride semiconductor, particularly GaN as in the first embodiment.

The main drift layer 11 is provided on the substrate 10 and contains a first conductivity type impurity at a lower concentration than the substrate 10. In the present embodiment, the main drift layer 11 is made of Si-doped n⁻-GaN. A Si concentration in the main drift layer 11 can be 3 × 10¹⁵/cm³ to 3 × 10¹⁶/cm³, and is 1 × 10¹⁶/cm³ in the present embodiment. A thickness of the main drift layer 11 can be 0.5 μm to 20 μm, and is 10 μm in the present embodiment.

The second conductivity type blocking layer 20 contains a second conductivity type impurity and is provided on the main drift layer 11. In the present embodiment, the second conductivity type blocking layer 20 is made of Mg-doped p-GaN and is also referred to as a p-type blocking layer 20. A Mg concentration in the p-type blocking layer 20 can be 5 × 10¹⁷/cm³ to 5 × 10¹⁹/cm³, and is 1 × 10¹⁹/cm³ in the present embodiment. A thickness of the p-type blocking layer 20 can be 0.3 μm to 1.0 μm, and is 0.5 μm in the present embodiment.

An opening 20a is formed in the second conductivity type blocking layer (p-type blocking layer) 20. In the present embodiment, the opening 20a is located on a lower side Y2 of the recess R to be described later. In the present embodiment, an end portion of the opening 20a in a lateral direction X does not reach a position of a wall surface of the gate trench T (to be described later) in the lateral direction X.

The second conductivity type connection layer 21 is provided on the second conductivity type blocking layer (p-type blocking layer) 20 and contains a second conductivity type impurity at a higher concentration than the second conductivity type blocking layer 20. In the present embodiment, the second conductivity type connection layer 21 is made of Mg-doped p-GaN, and is also referred to as a p-type connection layer 21. A Mg concentration in the p-type connection layer 21 can be 1 × 10¹⁸/cm³ to 6 × 10¹⁹/cm³, and is 3 × 10¹⁹/cm³ in the present embodiment. A thickness of the p-type connection layer 21 can be 0.4 μm to 4.0 μm, and is 1.3 μm in the present embodiment. A first source electrode SM1 to be described later is formed on the second conductivity type connection layer 21.

In the present embodiment, the second conductivity type connection layer 21 has a projecting portion 21a projecting toward the opening 20a along a bottom surface of the gate trench T to be described later. A projecting amount L1 of the projecting portion 21a is smaller than a width W1 of the bottom surface of the gate trench T. The width W1 of the bottom surface of the gate trench T can be 0.5 μm to 3.0 μm, and is 1.5 μm in the present embodiment. The projecting amount L1 can be 0 μm to 3 μm, and is 0.7 μm in the present embodiment.

The sub-drift layer 12 fills the opening 20a, is provided on the second conductivity type blocking layer 20, and contains a first conductivity type impurity at the same concentration as the main drift layer 11 or at a higher concentration than the main drift layer 11. In the present embodiment, the sub-drift layer 12 is made of Si-doped n⁻-GaN. A Si concentration in the sub-drift layer 12 can be 3 × 10¹⁵/cm³ to 3 × 10¹⁶/cm³, and is 1 × 10¹⁶/cm³ in the present embodiment. A thickness of the sub-drift layer 12 can be 0.1 μm to 1.5 μm, and is 1.0 μm in the present embodiment.

The second conductivity type body layer 30 is provided on the sub-drift layer 12 and the p-type blocking layer 20. The second conductivity type body layer 30 contains a second conductivity type impurity at the same concentration as the p-type blocking layer 20 or at a lower concentration than the p-type blocking layer 20. In the present embodiment, the second conductivity type body layer 30 is made of Mg-doped p-GaN, and is also referred to as a p-type body layer 30. A Mg concentration in the p-type body layer 30 can be 1 × 10¹⁷/cm³ to 4 × 10¹⁹/cm³, and is 5 × 10¹⁸/cm³ in the present embodiment. A thickness of the p-type body layer 30 can be 0.2 μm to 1.0 μm, and is 0.4 μm in the present embodiment.

The high concentration first conductivity type impurity-containing layer 13 is provided on the p-type body layer 30. The high concentration first conductivity type impurity-containing layer 13 contains a first conductivity type impurity at a higher concentration than the sub-drift layer 12 and at the same concentration as the substrate 10 or at a higher concentration than the substrate 10. In the present embodiment, the high concentration first conductivity type impurity-containing layer 13 is made of Si-doped n⁺-GaN and is also referred to as an n-type layer 13. A Si concentration in the n-type layer 13 can be 5 × 10¹⁷/cm³ to 1 × 10¹⁹/cm³, and is 2 × 10¹⁸/cm³ in the present embodiment. A thickness of the n-type layer 13 can be 0.1 μm to 0.5 μm, and is 0.2 μm in the present embodiment.

The gate trench T reaches at least the sub-drift layer 12 from the high concentration first conductivity type impurity-containing layer 13, and is formed in a groove shape to expose at least a part of a side surface of the second conductivity type connection layer (p-type connection layer) 21. In the present embodiment, the sub-drift layer 12 and the projecting portion 21a of the p-type connection layer 21 are exposed one the bottom surface of the gate trench T. The side surface of the p-type connection layer 21 is exposed on one side surface of the gate trench T, and the sub-drift layer 12, the p-type body layer 30, and the n-type layer 13 are exposed on the other side surface of the gate trench T in order from a bottom surface side. The p-type body layer 30 exposed on the other side surface of the gate trench T operates as a channel.

As described above, the width W1 of the bottom surface of the gate trench T can be 0.5 μm to 3 μm, and is 1.5 μm in the present embodiment. A cell pitch can be 3 μm to 10 μm, and is 6 μm in the present embodiment. A trench width can be 0.5 μm to 3 μm, and is 2 μm in the present embodiment. A trench angle is not limited, and is perpendicular to the substrate 10 in the present embodiment. In the present embodiment, as shown in FIG. 2, a plane pattern of the gate trench T has a stripe shape in which the gate trench T, the p-type body layer 30, and the p-type connection layer 21 are sequentially arranged in parallel.

The recess R is a recessed portion having a depth reaching the p-type body layer 30 through the n-type layer 13. The recess R is provided to bring the source electrode SM into contact with the p-type body layer 30.

The gate insulating film 14 is continuously provided in a film shape along the bottom surface, the side surface, and an upper surface of the gate trench T (on the n-type layer 13 near the gate trench T and an upper surface of the p-type connection layer 21). A material of the gate insulating film 14 is SiO₂, SiN, SiON, Al₂O₃, or the like, and a thickness thereof is, for example, 50 nm.

The gate electrode GM is continuously provided in a film shape along the bottom surface, the side surface, and the upper surface of the gate trench T via the gate insulating film 14. A material of the gate electrode GM is TiN or the like.

The source electrode SM includes the first source electrode SM1 and a second source electrode SM2. The first source electrode SM1 is formed on the p-type connection layer 21 as described above. The second source electrode SM2 is connected to the second conductivity type body layer 30 via the recess R formed in a groove shape to reach the second conductivity type body layer 30 from the high concentration first conductivity type impurity-containing layer 13. A material of the first source electrode SM1 and the second source electrode SM2 is, for example, Ti/Al, Ti/Al/Ti, V/Al/Ti, or Pd/Al/Ti.

The drain electrode DM is provided on an entire back surface of the substrate 10. A material of the drain electrode DM is, for example, Ti/Al, Ti/Al/Ti, V/Al/Ti, or Pd/Al/Ti.

### 2. Method for Producing Semiconductor Device

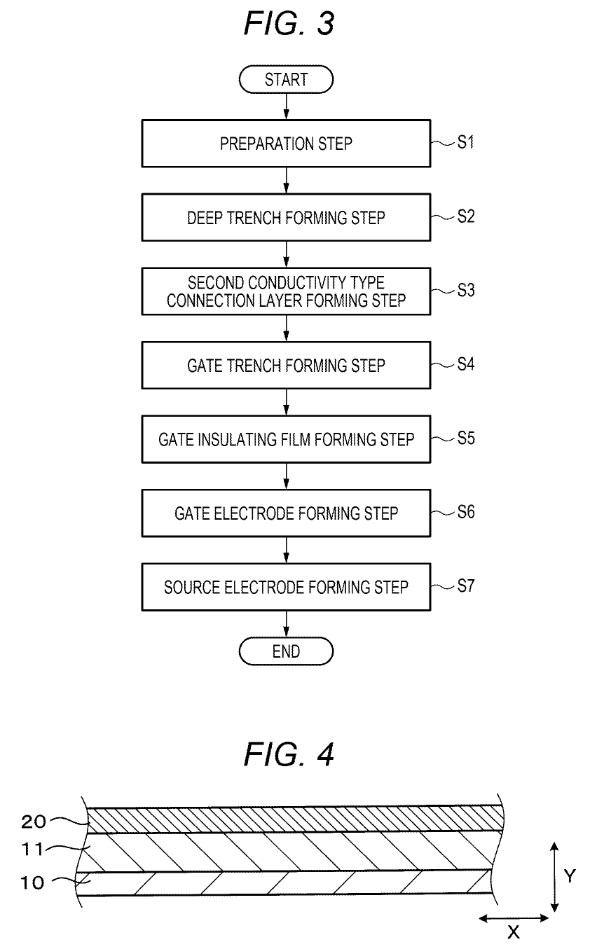

Next, a method for producing a semiconductor device according to the first embodiment will be described with reference to FIGS. 3-12.

First, in a preparation step S1 shown in FIG. 3, as shown in FIG. 4, the main drift layer 11 and the p-type blocking layer 20 are stacked on the substrate 10 in order from a substrate 10 side. Each layer is formed by using a vapor phase growth method such as an MOCVD method, an HVPE method, an MBE method, or a sputtering method, whereby Si as a first conductivity type impurity or Mg as a second conductivity type impurity has a predetermined doping concentration.

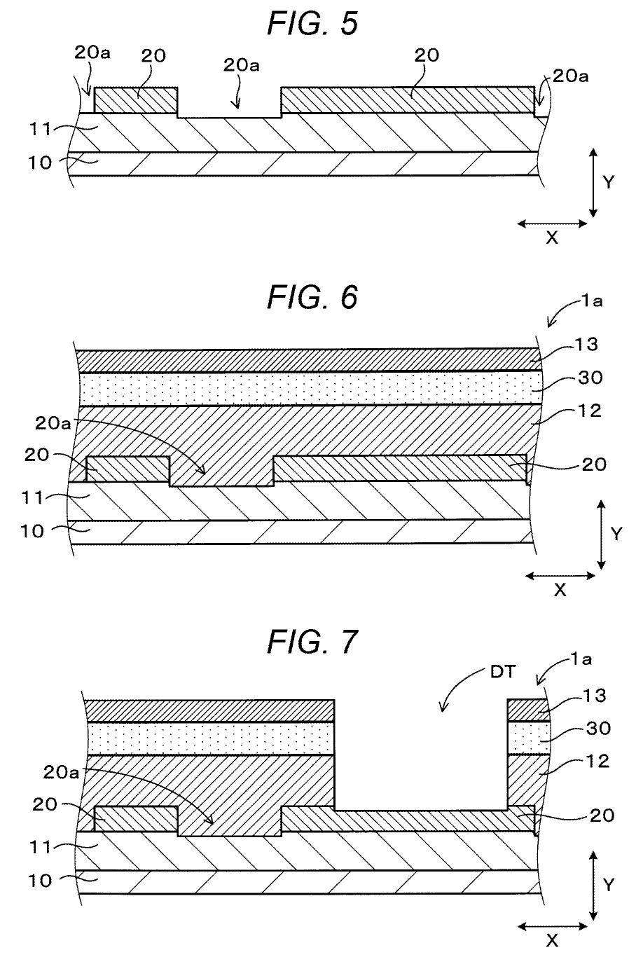

Next, after a predetermined mask pattern (not shown) is formed on the p-type blocking layer 20, etching is performed to remove the p-type blocking layer 20 until the main drift layer 11 is exposed, thereby forming the opening 20a, as shown in FIG. 5. The etching can be performed by dry etching such as RIE, wet etching such as PEC, or polishing. After the etching, the mask pattern (not shown) is removed.

Then, as shown in FIG. 6, the sub-drift layer 12, the p-type blocking layer 20, and the n-type layer 13 are sequentially formed on the p-type blocking layer 20 and the opening 20a. Note that, each layer is formed by using a vapor phase growth method such as an MOCVD method, an HVPE method, an MBE method, or a sputtering method, whereby Si as a first conductivity type impurity or Mg as a second conductivity type impurity has a predetermined doping concentration. Accordingly, the opening 20a is filled with the sub-drift layer 12. Accordingly, a stacked body 1a in which the substrate 10, the main drift layer 11, the p-type blocking layer 20, the sub-drift layer 12, the p-type body layer 30, and the n-type layer 13 are stacked is prepared.

Next, in a deep trench forming step S2 shown in FIG. 3, a predetermined mask pattern (not shown) is formed on the n-type layer 13 of the stacked body 1a, and as shown in FIG. 7, a deep trench DT, which is a groove reaching at least the p-type blocking layer 20 from the n-type layer 13 in the stacked body 1a, is formed by etching. The etching can be performed by dry etching such as RIE, wet etching such as PEC, or polishing. After the etching, the mask pattern (not shown) is removed.

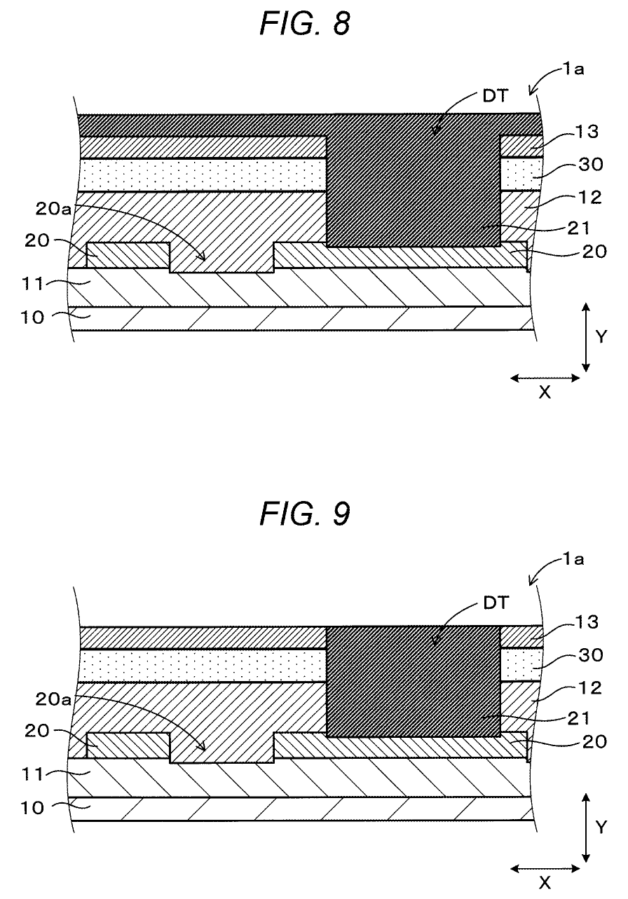

Next, in a second conductivity type connection layer forming step S3 shown in FIG. 3, as shown in FIG. 8, the second conductivity type connection layer (p-type connection layer) 21 is formed to fill the deep trench DT. The second conductivity type connection layer 21 is formed by using a vapor phase growth method such as an MOCVD method, an HVPE method, an MBE method, or a sputtering method, whereby Mg as a second conductivity type impurity has a predetermined doping concentration. Thereafter, as shown in FIG. 9, the excess second conductivity type connection layer 21 formed on the n-type layer 13 is removed by etching.

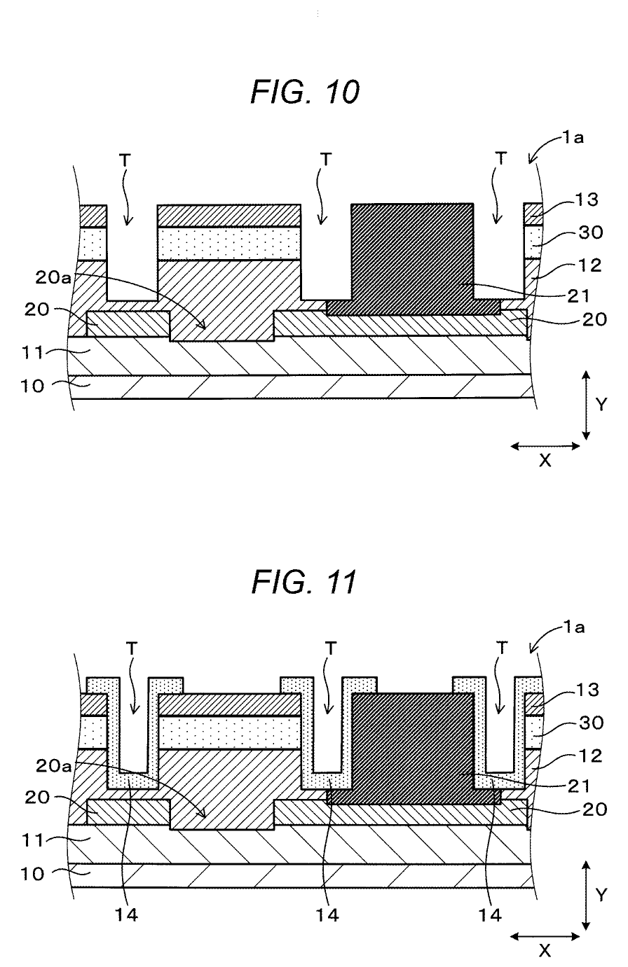

Next, in a gate trench forming step S4 shown in FIG. 3, as shown in FIG. 10, the gate trench T is formed by removing a region including a junction portion between a peripheral surface of the second conductivity type connection layer 21 and a wall surface of the deep trench DT from the high concentration first conductivity type impurity-containing layer 13 to at least the sub-drift layer 12 to expose at least a part of the side surface of the second conductivity type connection layer 21.

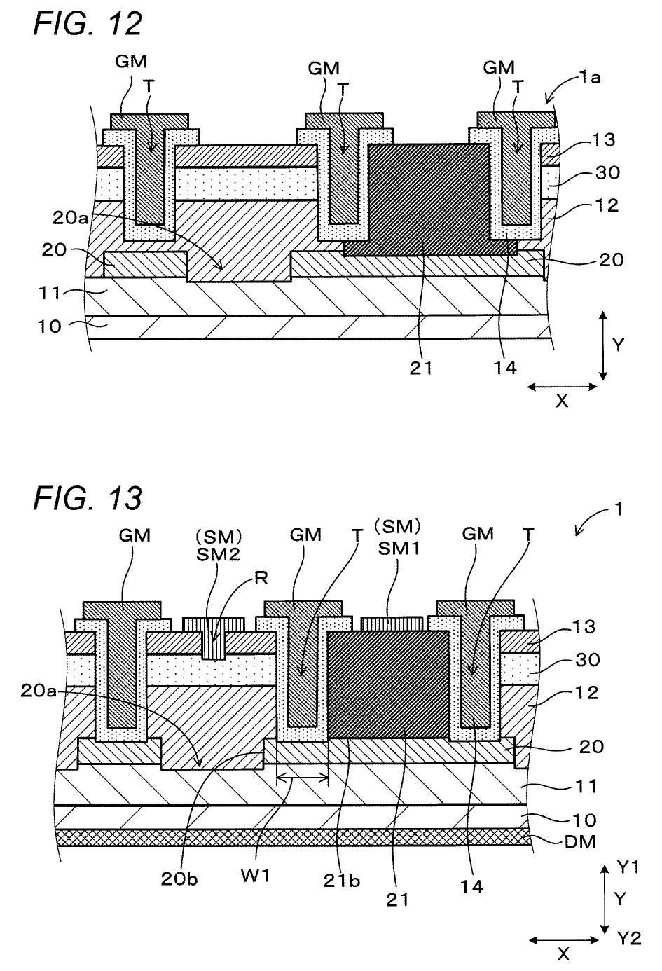

Next, in a gate insulating film forming step S5 shown in FIG. 3, as shown in FIG. 11, the gate insulating film 14 covering the bottom surface and the side surface of the gate trench T is formed. Examples of the method of forming the gate insulating film 14 include an ALD method or a CVD method. Thereafter, in a gate electrode forming step S6 shown in FIG. 3, as shown in FIG. 12, the gate electrode GM is formed along the bottom surface and the side surface of the gate trench T via the gate insulating film 14. In order to form the gate electrode GM on the gate insulating film 14, first, a uniform metal layer having the same stacked structure as the gate electrode GM is formed on the gate insulating film 14, and the uniform metal layer and the gate insulating film 14 are partially removed by etching using a resist or the like. Accordingly, as shown in FIG. 12, the gate electrode GM and the gate insulating film 14 are formed.

Then, in a source electrode forming step S7, the first source electrode SM1 connected to the second conductivity type connection layer 21 is formed. In addition, the second source electrode SM2 connected to the p-type body layer 30 via the groove-shaped recess R formed in the n-type layer 13 located above the opening 20a is formed, and the drain electrode DM is formed on the back surface of the substrate 10 to complete the semiconductor device 1 as shown in FIG. 1. The method of forming the source electrode SM and the drain electrode DM is vapor deposition or the like.

### 3. Operations and Effects

With the semiconductor device 1 according to the present embodiment, the second conductivity type blocking layer 20 is provided between the second conductivity type body layer 30 and the main drift layer 11 to alleviate electrolysis concentration on the bottom portion of the gate trench T and prevent the current leakage, thereby improving the breakdown voltage. Further, by connecting the second conductivity type blocking layer 20 and the first source electrode SM1 by the second conductivity type connection layer 21, the second conductivity type blocking layer 20 is prevented from electrically floating, and the occurrence of the switching loss is prevented. In addition, since the gate trench T is formed to expose at least a part of the side surface of the second conductivity type connection layer 21 and the side surface of the second conductivity type connection layer 21 exposed in the gate trench T is covered by the gate insulating film 14 covering the wall surface of the gate trench T, at least a part of a high concentration n-type region on the side surface of the second conductivity type connection layer 21 can be removed and the side surface can be insulated. As a result, formation of a leakage path is prevented, and a decrease in breakdown voltage can be prevented. Therefore, the semiconductor device 1 according to the present embodiment can achieve both an improvement in breakdown voltage and a reduction in switching loss.

In addition, in the present embodiment, in the semiconductor device 1, the second conductivity type connection layer 21 has the projecting portion 21a projecting toward the opening 20a along the bottom surface of the gate trench T, and the projecting amount L1 of the projecting portion 21a projecting from the side surface of the gate trench T is smaller than the width W1 of the bottom surface of the gate trench T. Accordingly, a function of a transistor portion formed in a region including the opening 20a in the semiconductor device 1 can be ensured.

In addition, in the method for producing the semiconductor device 1 according to the present embodiment, the gate trench T is formed by removing the region including the junction portion between the peripheral surface of the second conductivity type connection layer 21 and the wall surface of the deep trench DT from the high concentration first conductivity type impurity-containing layer 13 to at least the sub-drift layer 12, at least a part of the side surface of the second conductivity type connection layer 21 is exposed to the wall surface of the gate trench T, and the side surface of the second conductivity type connection layer 21 exposed to the wall surface of the gate trench T is covered with the gate insulating film 14. Accordingly, it is possible to produce the semiconductor device 1 capable of achieving both an improvement in breakdown voltage and a reduction in switching loss.

As described above, according to the present embodiment, it is possible to provide the semiconductor device 1 capable of achieving both an improvement in breakdown voltage and a reduction in switching loss.

### Second Embodiment

In the semiconductor device 1 according to the first embodiment, as shown in FIG. 1, a bottom surface 21b of the second conductivity type connection layer 21 is located on a side opposite to a side where the high concentration first conductivity type impurity-containing layer 13 is located with respect to the bottom surface of the gate trench T, but instead, in the semiconductor device 1 according to a second embodiment, as shown in FIG. 13, the bottom surface 21b of the second conductivity type connection layer 21 is located on the side where the high concentration first conductivity type impurity-containing layer 13 is located with respect to the bottom surface of the gate trench T. Accordingly, since the second conductivity type connection layer 21 does not project to the bottom surface of the gate trench T, the breakdown voltage can be further improved.

In addition, in the semiconductor device 1 according to the second embodiment, the entire side surface of the second conductivity type connection layer 21 is exposed to the gate trench T and covered with the gate insulating film 14. Accordingly, it is possible to further improve the breakdown voltage and reduce the switching loss.

Note that, other configurations in the second embodiment are the same as those in the first embodiment, and the same reference numerals as those in the first embodiment are given and description thereof is omitted. The second embodiment has the same operations and effects as in the case of the first embodiment.

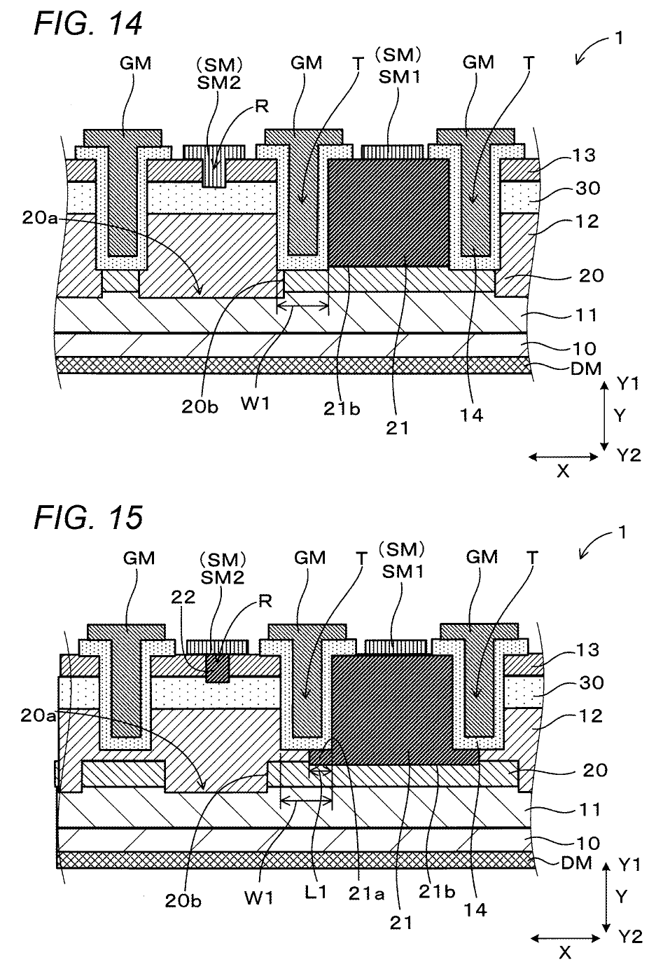

In addition, in the semiconductor device 1 according to the second embodiment, as shown in FIG. 13, an end surface 20b of the second conductivity type blocking layer 20 in the lateral direction X is located on an opening 20a side with respect to the wall surface of the gate trench T, but instead, in the semiconductor device 1 according to a first modification, as shown in FIG. 14, the end surface 20b of the second conductivity type blocking layer 20 in the lateral direction X is located on a side opposite to the opening 20a with respect to the wall surface of the gate trench T. Accordingly, an electric field strength under the gate trench T is increased, so that the breakdown voltage decreases, but a wide current path can be ensured, so that on-resistance can be decreased.

### Third Embodiment

In the semiconductor device 1 according to the first embodiment, as shown in FIG. 1, the second source electrode SM2 enters the recess R and is directly connected to the second conductivity type body layer 30, but instead, in the semiconductor device 1 according to a third embodiment, as shown in FIG. 15, there is provided a second conductivity type hole filling layer 22 that is provided to fill the recess R formed in a groove shape to reach the second conductivity type body layer 30 from the high concentration first conductivity type impurity-containing layer 13 and that contains a second conductivity type impurity at a higher concentration than the second conductivity type body layer 30, and the second source electrode SM2 is provided to cover the second conductivity type hole filling layer 22. Accordingly, the breakdown voltage of the semiconductor device 1 can be further improved.

In the present embodiment, the second conductivity type hole filling layer 22 is made of Mg-doped p-GaN, and is also referred to as a p-type filling layer 22. A Mg concentration in the p-type filling layer 22 can be equal to that in the second conductivity type connection layer 21, can be 1 × 10¹⁸/cm³ to 6 × 10¹⁹/cm³, and is 3 × 10¹⁹/cm³ in the present embodiment.

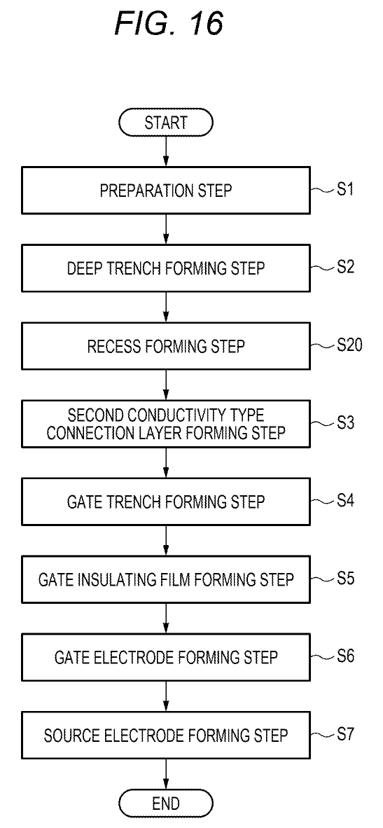

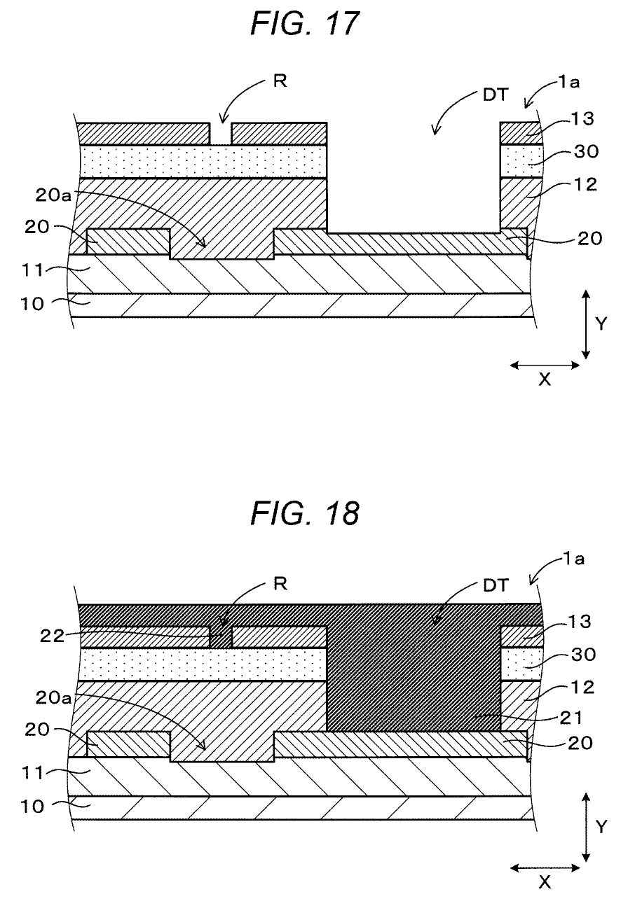

In a method for producing the semiconductor device 1 according to the third embodiment, as shown in FIG. 16, a recess forming step S20 is performed after the deep trench forming step S2. In the recess forming step S20, as shown in FIG. 17, the recess R is formed by removing a region above the opening 20a from the high concentration first conductivity type impurity-containing layer 13 to the second conductivity type body layer 30.

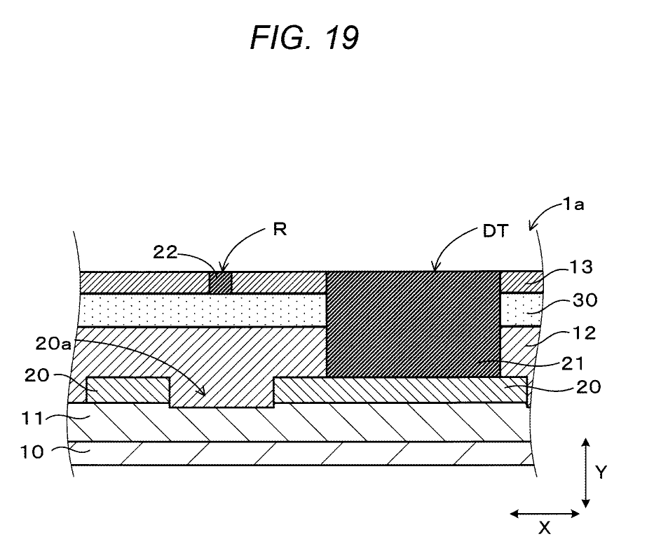

Then, after the recess forming step S20 shown in FIG. 16, in the second conductivity type connection layer forming step S3, as shown in FIG. 18, the deep trench DT is filled to form the second conductivity type connection layer 21, and the recess R is filled to form the second conductivity type hole filling layer 22, and as shown in FIG. 19, the second conductivity type connection layer 21 and the second conductivity type hole filling layer 22 that are excessive in the high concentration first conductivity type impurity-containing layer 13 are removed by etching. Therefore, in the present embodiment, the second conductivity type hole filling layer 22 is formed of the same material as the second conductivity type connection layer 21.

Then, in the source electrode forming step S7 shown in FIG. 16, as shown in FIG. 15, the first source electrode SM1 connected to the second conductivity type connection layer 21 is formed, the second source electrode SM2 provided to cover the second conductivity type hole filling layer 22 is formed, and the drain electrode DM is formed, to complete the semiconductor device 1.

With the method for producing the semiconductor device 1 according to the third embodiment, the breakdown voltage of the semiconductor device 1 can be further improved. Note that, other steps shown in FIG. 16 in the third embodiment are the same as the steps shown in FIG. 3 in the first embodiment, and the same reference numerals are given and description thereof is omitted. The method for producing the semiconductor device 1 according to the third embodiment also has the same operations and effects as the method for producing the semiconductor device 1 according to the first embodiment.

The first conductivity type impurity is of n type and the second conductivity type impurity is of p type in the first to third embodiments and the first modification. Alternatively, the first conductivity type impurity may be of p type and the second conductivity type impurity may be of n type.

### REFERENCE SIGNS LIST

1: semiconductor device
10: substrate
11: main drift layer
12: sub-drift layer
13: high concentration first conductivity type impurity-containing layer (n-type layer)
14: gate insulating film
20: second conductivity type blocking layer (p-type blocking layer)
21: second conductivity type connection layer (p-type connection layer)
22: second conductivity type hole filling layer (p-type filling layer)
30: second conductivity type body layer (p-type body layer)
DM: drain electrode
GM: gate electrode
R: recess
SM: source electrode
T: gate trench

What is claimed is:

1. A semiconductor device comprising:
a substrate comprising a semiconductor containing a first conductivity type impurity;
a main drift layer provided over the substrate and containing a first conductivity type impurity at a lower concentration than the substrate;
a second conductivity type blocking layer provided over and in contact with the main drift layer, having an opening, and containing a second conductivity type impurity;
a second conductivity type connection layer provided over the second conductivity type blocking layer and containing a second conductivity type impurity at a higher concentration than the second conductivity type blocking layer;
a source electrode connected to the second conductivity type connection layer;
a sub-drift layer filling the opening, provided over the second conductivity type blocking layer, and containing a first conductivity type impurity at a same concentration as the main drift layer or at a higher concentration than the main drift layer;
a second conductivity type body layer provided over the sub-drift layer and the second conductivity type blocking layer, and containing a second conductivity type impurity at a same concentration as the second conductivity type blocking layer or at a lower concentration than the second conductivity type blocking layer;
a high concentration first conductivity type impurity-containing layer provided over the second conductivity type body layer and containing a first conductivity type impurity at a higher concentration than the sub-drift layer;
a gate trench formed in a groove shape to reach at least the sub-drift layer from the high concentration first conductivity type impurity-containing layer and to expose at least a part of a side surface of the second conductivity type connection layer;
a gate insulating film provided in a film shape along a bottom surface and a side surface of the gate trench and covering the side surface of the second conductivity type connection layer exposed in the gate trench; and
a gate electrode provided along the bottom surface and the side surface of the gate trench via the gate insulating film.

2. The semiconductor device according to claim 1, wherein
the second conductivity type connection layer has a projecting portion projecting toward the opening along the bottom surface of the gate trench, and
a projecting amount of the projecting portion is smaller than a width of the bottom surface of the gate trench.

3. The semiconductor device according to claim 1, wherein a bottom surface of the second conductivity type connection layer is located closer to a side where the high concentration first conductivity type impurity-containing layer is located than the bottom surface of the gate trench is.

4. The semiconductor device according to claim 2, wherein a bottom surface of the second conductivity type connection layer is located closer to a side where the high concentration first conductivity type impurity-containing layer is located than the bottom surface of the gate trench is.

5. The semiconductor device according to claim 1, wherein an entire area of the side surface of the second conductivity type connection layer is exposed to the gate trench and covered with the gate insulating film.

6. The semiconductor device according to claim 2, wherein an entire area of the side surface of the second conductivity type connection layer is exposed to the gate trench and covered with the gate insulating film.

7. The semiconductor device according to claim 1, further comprising:
a recess formed to reach the second conductivity type body layer from the high concentration first conductivity type impurity-containing layer; and
a second conductivity type hole filling layer provided to fill the recess and containing a second conductivity type impurity at a higher concentration than the second conductivity type blocking layer, wherein
the source electrode is provided to cover the second conductivity type hole filling layer.

8. The semiconductor device according to claim 2, further comprising:
a recess formed to reach the second conductivity type body layer from the high concentration first conductivity type impurity-containing layer; and
a second conductivity type hole filling layer provided to fill the recess and containing a second conductivity type impurity at a higher concentration than the second conductivity type blocking layer, wherein
the source electrode is provided to cover the second conductivity type hole filling layer.

9. A method for producing the semiconductor device according to claim 1, the method comprising:
preparing a stacked body in which the substrate, the main drift layer, the second conductivity type blocking layer, the sub-drift layer, the second conductivity type body layer, and the high concentration first conductivity type impurity-containing layer are stacked;
forming a deep trench, which is a groove reaching at least the second conductivity type blocking layer from the high concentration first conductivity type impurity-containing layer in the stacked body;
forming the second conductivity type connection layer so as to fill the deep trench;
forming the gate trench by removing a region including a junction portion between a peripheral surface of the second conductivity type connection layer and a wall surface of the deep trench from the high concentration first conductivity type impurity-containing layer to at least the sub-drift layer to expose at least a part of the side surface of the second conductivity type connection layer;
forming the gate insulating film covering the bottom surface and the side surface of the gate trench;
forming the gate electrode along the bottom surface and the side surface of the gate trench via the gate insulating film; and
forming the source electrode connected to the second conductivity type connection layer.

10. The method according to claim 9, further comprising:
forming the recess by removing a region over the opening from the high concentration first conductivity type impurity-containing layer to the second conductivity type body layer after the forming of the deep trench, wherein
after the forming of the recess, in the forming of the second conductivity type connection layer, the deep trench is filled to form the second conductivity type connection layer, and the recess is filled to form a second conductivity type hole filling layer.
